(19) United States
(12) Patent Application Publication
(10) Pub. No.: US 2003/0183416 A1
(43) Pub. Date: Oct. 2, 2003

(54) Method of electrically coupling an electronic component to a substrate

(76) Inventors: Jerry L. White, Glendale, AZ (US); Scott E. Lindsey, Brentwood, CA (US); Drew W. Delaney, Gilbert, AZ (US)

Correspondence Address: MOTOROLA, INC., CORPORATE LAW DEPARTMENT - #56-238, 3102 NORTH 56TH STREET, PHOENIX, AZ, 85018, US

(21) Appl. No.: 10/113,026

(22) Filed: Mar. 29, 2002

(51) Int. Cl. H05K 1/18; H05K 3/30

(52) U.S. Cl. 174/257; 174/260; 29/842; 29/840

(57) ABSTRACT

A method of electrically coupling a first substrate (12) and a second substrate (30) includes forming a conductive bump (20) on the first substrate (12) by electroless plating a metal and nonconductive particles (26) together. The first substrate (12) and the second substrate (30) are bonded with a nonconductive polymer (40) so that the conductive bump (20) and a conductive pad (32) of the second substrate 30) are electrically coupled.

### BACKGROUND OF THE INVENTION

This invention relates, in general, to processing of electronic components, and more particularly, to a method of electrically coupling an electronic component to a substrate.

An Anisotropic Conductive Film (ACF) or Anisotropic Conductive Adhesive (ACA) has been used to bond an electronic component having a bump formed thereon to the terminal of an external substrate. The ACF and ACA contain conductive particles which are 5 to 7 microns large in diameter that enhance the coupling of the bump to the terminal of the external substrate.

As the size of semiconductor devices becomes smaller, the distance between the bumps formed on the electronic component becomes smaller. The adjacent bumps can be electrically coupled to each other through the conductive particles contained in ACF or ACA. This causes an electrical short in the electronic component.

The ACF or ACA can be fabricated to contain less conductive particles to avoid shorting between adjacent bumps on the electronic component. However, there is a delicate balance between having enough conductive particles to ensure contact between the bump and the substrate and few enough conductive particles to avoid shorting between adjacent bumps of the electronic component.

Several approaches have been developed to solve this problem. One process involves magnetically dispersing the conductive particles during a soft curing of the ACF or using a photoimagable material to predefine the areas where the conductive particles are placed in the ACF. While these techniques have had some success, they are laborious and expensive.

Another process set forth in U.S. Pat. No. 5,083,697, issued to DiFrancesco, discloses a method of making a bump by depositing metallized hard particles. The metallized hard particles enhance the contact surface to make better electrical contact. The patent states that the metallized hard particles are deposited using conventional metal coating techniques, including electroplating, electroless plating, chemical vapor deposition (CVD), sputter deposition, evaporation. While this process is believed to achieve some success, the process of depositing these metallized hard particles is lengthy and costly. Thus, it would be desirable to have a process that is less expensive and easier to manufacture.

Accordingly, there is a need for developing a less costly process that enables the electrical coupling of an electronic component to a substrate without creating shorts between bumps on the electronic component and yet providing a bump topography which ensures a reliable electrical coupling between the bump and the substrate.

### BRIEF DESCRIPTION OF THE DRAWINGS

FIG. 1 illustrates a cross-sectional view of an electronic component in accordance with a preferred embodiment of the present invention;

FIG. 2 illustrates, in a cross-sectional view, the electronic component of FIG. 1 electrically coupled to a substrate in accordance with the present invention;

FIG. 3 illustrates a flowchart of a method in accordance with a preferred embodiment of the present invention; and

FIG. 4 illustrates a cross-sectional view of a portion of an electronic component in accordance with a preferred embodiment of the present invention.

### DETAILED DESCRIPTION OF THE PREFERRED EMBODIMENTS

The present invention relates to structures and methods for electrically coupling two elements. More particularly, the present invention relates to electrically coupling an electronic component having a bump formed thereon to an external substrate.

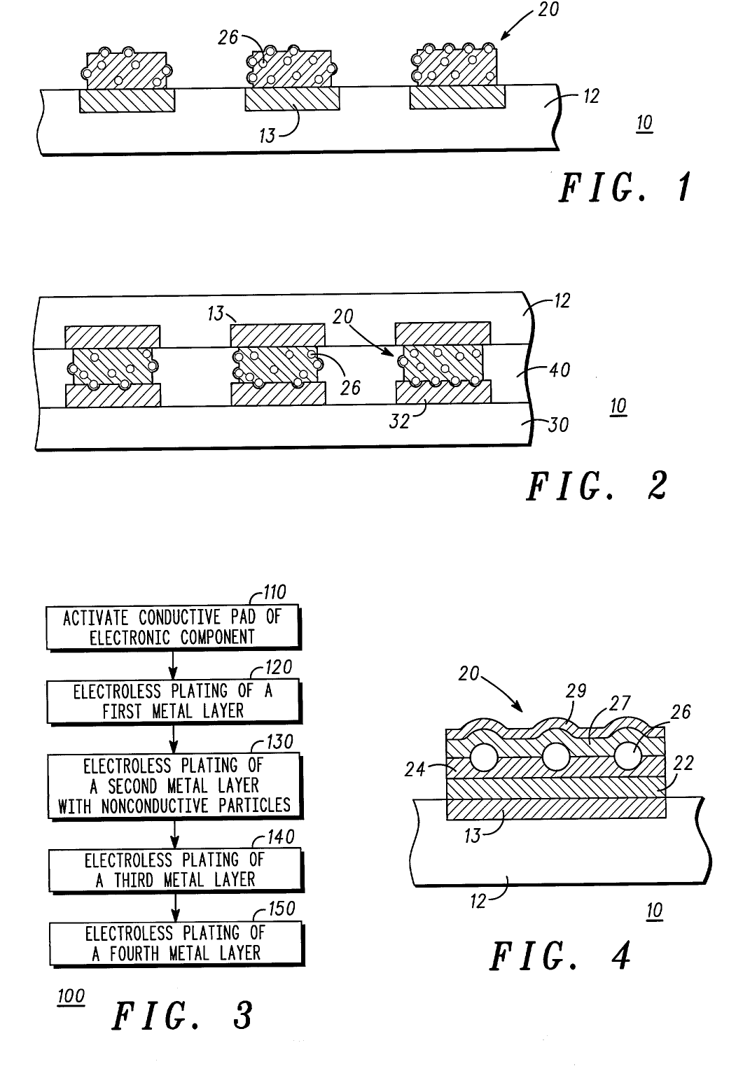

FIG. 1 is a cross-sectional view of an electronic component 10 having an electrode or conductive bump 20 formed thereon. Electronic component 10 can by any type of component that makes electrical connection to an external surface. Electronic component 10 may be a semiconductor chip, a printed circuit board, a liquid crystal display, or the like. For convenience, electronic component 10 will be described as a semiconductor chip. Thus, electronic component 10 is comprised of a substrate 12 having a conductive pad 13 formed thereon. An electrode or conductive bump 20 is formed on the conductive pad 13. Conductive bump 20 has nonconductive particles 26 formed therein. The formation of conductive bump 20 will be explained in further detail with reference to FIGS. 3 and 4.

FIG. 2 illustrates, in a cross-sectional view, the electronic component 10 of FIG. 1 electrically coupled to a substrate 30 in accordance with the present invention. Substrate 30 is any external element having a conductive pad 32 formed thereon to which electronic component 10 is to be electrically coupled. Substrate 30 may be a printed circuit board, Tape Automated Bonding (TAB) flexible tape, polyimide tape, or the like for which electronic component 10 is bonded thereto. Electrical component 10 is bonded to substrate 30 through a nonconductive polymer 40. Nonconductive polymer 40 may be comprised of a thermoset epoxy. The present invention utilizes a nonconductive polymer 40, which is much less expensive than the conductive films used in prior art applications. The top surface of the conductive bump 20 actually makes physical contact with conductive pad 32 of the substrate 30.

The electrical coupling of electronic component 10 and substrate 30 is carried out by applying nonconductive polymer 40 in liquid form or in film form, to either electronic component 10 or substrate 30. Preferably, nonconductive polymer 40 is applied to substrate 30 and then electronic component 10 is placed adjacent to substrate 30 and pressure and some temperature (between approximately 195 and 200° C.) is applied, thereby forming a permanent coupling of electronic component 10 and substrate 30. Suitable pressure is applied to ensure bonding.

As one can see by FIG. 2, the nonconductive particles 26 of conductive bump 20 enhance the electrical coupling of conductive bump 20 to conductive pad 32 by providing a topography which enhances electrical coupling. The nonconductive particles 26 create a roughened surface to conductive bump 20 that penetrates the surface of conductive pad 32.

Now with reference to FIGS. 3 and 4. FIG. 3 illustrates a flow chart 100 that is a preferred embodiment of the present invention. FIG. 4 illustrates an enlarged cross-sectional view of a small portion of electronic component 10. Semiconductor chip 12 having the conductive pad 13 formed thereon is provided. Conductive bump 20 is formed as follows. First, in step 110, conductive pad 13 is activated by a thin layer of a metal. The activation step is dependent upon the type of metal that comprises a first metal layer 22. For example, if first metal layer 22 comprises electroless nickel, then zincation is a suitable activation step, if first metal layer 22 comprises electroless copper (Cu), then a palladium activation may be used. The activation step is performed by exposing electronic component 10 to a commercially available bath that is comprised of, for example, zinc or palladium. The activation step is performed in order to improve adhesion between conductive pad 13 and a subsequently deposited first metal layer 22.

In step 120, the first metal layer 22 is deposited over the surface of conductive pad 13 by electroless plating. Preferably, first metal layer 22 has a thickness in the range of approximately 2 to 5 microns. First metal layer 22 is preferably comprised of nickel, in particular, nickel-cobalt (NiCo) or nickel-iron (NiFe). Instead of nickel, first metal layer 22 may also be comprised of copper (Cu).

Next, in step 130, nonconductive particles 26 and a second metal layer 24 are co-deposited over the surface of the first metal layer 22 through electroless plating. In a preferred embodiment, second metal layer 24 is also comprised of nickel having a thickness in the range of approximately 2 to 5 microns and nonconductive particles 26 are comprised of alumina (Al₂O₃). The alumina preferably has a diameter in the range of approximately 5 to 10 microns. Other types of nonconductive particles 26 may be used, such as other oxides, or silicon carbide (siC).

Note that nonconductive particles 26 are shown to be of the same size and deposited at the same depth within the second metal layer 22 for ease of illustration only. It should be understood that the co-deposition of nonconductive particles 26 and the second metal layer 24 results in more random placement of nonconductive particles 26. It should be also be understood that although the shape of nonconductive particles 26 has been described as a diameter, the invention is not limited to using particles having a spherical shape. Nonconductive particles 26 may be of any shape and a diameter may be equivalent to a width or length of nonconductive particles 26.

In step 140, a coating of a third metal layer 27 is deposited over the surface of the co-deposited second metal layer 24 and nonconductive particles 26 by electroless plating. Preferably, third metal layer 27 is comprised of nickel and has a thickness in the range of approximately 2 to 5 microns.

Lastly, in step 150, a fourth metal layer 29 is deposited over the third metal layer 27. In a preferred embodiment, fourth metal layer 29 has a thickness in the range of approximately 100 to 300 angstroms. Fourth metal layer 29 is preferably formed by a process called immersion. Preferably, fourth meal layer 29 is comprised of gold and is formed by placing electronic component 10 in a solution comprising a gold salt, sodium sulfite, wetting agents and potassium hydroxide to control the pH. This immersion process is self-limiting in thickness in that this plating process ceases once a coating of fourth metal layer 29 is formed overlying third metal layer 27.

The sequence of the formation of each layer is important to provide a reliable conductive bump 20. Metal layers 22, 24, 27, and 29 and the nonconductive particles 26 are placed in this sequence to provide an electrical connection to bump 20. In addition, metal layers 27 and 29 provide a fully conductive surface to conductive bump 20, as opposed to leveling out the surface of conductive bump 20. The conductive bump 20 is preferably formed using electroless plating which is suitable for use with semiconductor chips, while electroplating is not typically suitable in this application.

By now it should be appreciated that structures and methods have been provided for improving the electrical coupling of two substrates. In particular, the aforementioned advantages are obtained by forming a conductive bump 20 on a substrate, wherein the conductive bump has an enhanced contact area by co-depositing nonconductive particles 26 with a metal layer by electroless plating. The nonconductive particles 26 provide a topography of conductive bump 20 which enhances electrical conductivity between the two substrates.

Thus, a process for electrically coupling two substrates, which fully meets the advantages set forth above, has been provided. Although the invention has been described and illustrated with reference to specific illustrative embodiments, it is not intended that the invention be limited to those illustrative embodiments. Those skilled in the art will recognize that variations and modifications can be made without departing from the spirit of the invention. Therefore, all such variations and modifications as fall within the scope of the appended claims and equivalents thereof are intended to be included within the invention.

1. A method of electrically coupling a first and a second substrate comprising the steps of:
providing a first substrate;
providing a second substrate having a conductive pad formed thereon;
forming a conductive bump on the first substrate by electroless plating a first metal layer and nonconductive particles together;
bonding the first substrate and the second substrate with a nonconductive polymer so that the conductive bump and the conductive pad are electrically coupled.

2. The method of claim 1 wherein the step of forming the conductive bump further comprises the steps of:
electroless plating a second metal layer before the step of electroless plating the first metal layer and the nonconductive particles together; and
electroless plating a third metal layer after electroless plating the first metal layer and the nonconductive particles together.

3. The method of claim 2 wherein the steps of:
electroless plating the second metal layer before the step of electroless plating the first metal layer and the nonconductive particles together comprises forming the second metal layer having a thickness in the range of approximately 2 to 5 microns;
electroless plating the first metal layer and nonconductive particles together comprises forming the first metal layer and the nonconductive particles having a thickness in the range of approximately 2 to 5 microns; and
electroless plating the third metal layer after electroless plating the first metal layer and the nonconductive particles together comprises forming the third metal layer having a thickness in the range of approximately 2 to 5 microns.

4. The method of claim 3 wherein the step of
electroless plating the second metal layer before the step of electroless plating the first metal layer and the nonconductive particles together comprises forming the second metal layer comprised of nickel;
electroless plating the first metal layer and nonconductive particles together comprises forming the first metal layer comprised of nickel; and
electroless plating the third metal layer after electroless plating the first metal layer and the nonconductive particles together comprises forming the third metal layer comprised of nickel.

5. The method of claim 3 wherein the step of
electroless plating the second metal layer before the step of electroless plating the first metal layer and the nonconductive particles together comprises forming the second metal layer comprised of copper.

6. The method of claim 2 further comprising the step of:
forming a fourth metal layer over the third metal layer.

7. The method of claim 6 wherein the step of forming the fourth metal layer comprises forming the fourth metal layer by immersion.

8. The method of claim 7 wherein the step of forming the fourth metal layer comprises forming the fourth metal layer comprised of gold.

9. The method of claim 1 wherein the step of forming the conductive bum p comprises electroless plating of the first metal layer and nonconductive particles comprised of aluminum oxide, an oxide or silicon carbide.

10. The method of claim 9 wherein the step of forming the conductive bump comprises electroless plating of the first metal layer and of nonconductive particles having a diameter in the range of approximately 5 to 10 microns.

11. The method of claim 1 wherein the step of forming the conductive bump comprises electroless plating of the first metal layer comprised of nickel and nonconductive particles.

12. A method of making an electronic component comprising the steps of:
providing a first substrate having a first conductive pad formed thereon;
providing a second substrate having a second conductive pad formed thereon;
forming a first metal layer over the first conductive pad;
forming a second metal layer having nonconductive particles therein over the first metal layer;
forming a third metal layer over the second metal layer; and
bonding the first substrate and the second substrate with a nonconductive polymer, wherein the nonconductive particles facilitate electrical coupling of the first substrate and the second substrate.

13. The method of claim 12 further comprising the step of:
forming a fourth metal layer over the third metal layer.

14. An electronic component, comprising:
a first substrate;
a first conductive pad formed on the substrate;
a first metal layer formed over the first conductive pad;
a second metal layer having conductive particles formed therein formed over the first metal layer;
a third metal layer formed over the second metal layer; and
a fourth metal layer formed over the third metal layer.

15. The electronic component of claim 14 wherein the first metal layer is comprised of nickel.

16. The electronic component of claim 14 wherein the second metal layer is comprised of nickel.

17. The electronic component of claim 14 wherein the third metal layer is comprised of nickel.

18. The electronic component of claim 14 wherein the fourth metal layer is comprised of gold.

19. The electronic component of claim 14 wherein the nonconductive particles are comprised of alumina, an oxide, or silicon carbide.

20. The electronic component of claim 15 wherein the nonconductive particles have a diameter in the range of approximately 5 to 10 microns.

21. The electronic component of claim 14 further comprising:
a second substrate having a second conductive pad formed thereon;
a conductive polymer bonding the first substrate and the second substrate, wherein the second conductive pad and the conductive bump are electrically coupled.
